(19) United States
(12) Patent Application Publication
(10) Pub. No.: US 2026/0243836 A1
(43) Pub. Date: Aug. 20, 2026

(54) ENERGY STORAGE SYSTEM WITH STATE OF BALANCE LOGIC

(71) Applicant: Fluence Energy, LLC, Arlington, VA (US)

(72) Inventors: Thomas J. Winter, Decatur, GA (US); Hao Yuan Shi, Houston, TX (US)

(73) Assignee: Fluence Energy, LLC, Arlington, VA (US)

(21) Appl. No.: 19/531,740

(22) Filed: Feb. 6, 2026

Related U.S. Application Data
(60) Provisional application No. 63/760,847, filed on Feb. 20, 2025.

(51) Int. Cl. G01R 31/3842; G01R 31/367; G01R 31/374; G01R 31/3828; G01R 31/396; H02J 7/52; H02J 7/82

(52) U.S. Cl. CPC G01R 31/3842; G01R 31/367; G01R 31/374; G01R 31/3828; G01R 31/396; H02J 7/52; H02J 7/82

(57) ABSTRACT

A state of balance tool for an energy storage system (ESS) includes a processor and memory on which is recorded instructions. Execution of the instructions by the processor causes the tool to receive raw sensor data from a sensor suite, identify a threshold SoC imbalance in the ESS using the raw sensor data, and identify an element location in the ESS of a corresponding battery element having the imbalance. A control action is executed in response to the imbalance by transmitting an electronic signal indicative of the element location. A method for use with the ESS includes receiving the raw sensor data from the sensor suite, identifying the threshold SoC imbalance via a processor using the raw sensor data, identifying an element location of a corresponding node having the threshold imbalance, and executing a control action via the processor in response to the imbalance.

### CROSS-REFERENCE TO RELATED APPLICATIONS

The present application claims the benefit of priority to United States Provisional Application No. 63/760,847 filed on February 20, 2025, which is hereby incorporated by reference in its entirety.

### INTRODUCTION

The concepts described herein relate generally to battery-based energy storage systems, and more specifically to systems and methods for identifying and addressing state of charge (SoC) imbalances within an energy storage systems (ESS) to optimize energy retention, extend system life, and improve system-wide operational efficiency.

A modular energy storage system (ESS) can be constructed from one or more racks of series-connected and/or parallel-connected battery modules to provide standby energy storage capacity. For instance, an ESS may serve as an uninterruptible power supply for electrical grid power. Each of the battery modules of an ESS may contain an application-suitable number of electrochemical battery cells, e.g., rechargeable lithium-ion cells, with the battery cells positioned in the battery modules and the battery modules securely housed within an outer enclosure. In a typical application, the constituent battery cells of the ESS are charged during periods of reduced demand, e.g., using electrical power from solar panels, the grid, wind turbines, or a dedicated generator. The ESS later discharges its stored electrical power to the grid during periods of increased demand or during power outages. Proper operation of the ESS requires monitoring of real-time performance data and rapid response to fluctuations in grid power.

### SUMMARY

Disclosed herein are systems and methods for enhancing energy storage performance through an intelligent state-of-balance assessment engine, leveraging historical performance analytics, and real-time tracking of events to proactively adjust manual or automated balancing strategies. The present solutions pertain to locating and addressing imbalances in an energy storage system (ESS) of the type summarized above. The term “imbalance” as used herein refers to a state in which one or more electrochemical battery elements of the ESS have a different state of charge (SoC) relative to the ESS’s remaining battery cells. As appreciated by those skilled in the art, an ESS is performance constrained when a given battery cell of the ESS fails to attain a maximum/top of charge during a charging mode, or when the ESS fails to reach a minimum/bottom of charge during a discharging mode. An imbalanced state results in inaccessible energy capacity, i.e., stranded energy, and thus is undesirable. Therefore, the present hardware and software-based solutions are intended to facilitate accurate detection, location, and correction of an imbalanced state in the ESS.

Unlike conventional passive balancing approaches, the disclosed technology integrates multi-tiered balancing mechanisms and a dynamic SoC prediction model to ensure real-time SoC stabilization without manual intervention. Benefits of applying the present teachings to the management of an ESS include enhanced decision making and operational cost savings, increased efficiency due to automated monitoring and predictive maintenance, and reduced downtime, operational disruptions, and capital costs relative to competing approaches. Further, the present teachings may be used to inform an automated rebalancing strategy that preferentially allots balancing time to elements of the ESS which have greater levels of imbalance.

In accordance with a representative embodiment, a “state of balance” tool for an ESS having a plurality of electrochemical battery elements includes a sensor suite, a processor, and a computer storage medium (“memory”). Depending on the application/intended end use, the ESS may include one or more battery racks each having one or more battery modules. Each battery module includes an application-specific number of electrochemical battery cells. The battery elements considered therefore herein may include the battery cells, the battery modules, or the battery racks in different implementations. The sensor suite is operable for sensing thermoelectric properties of the battery elements and outputting raw sensor data indicative of the sensed thermoelectric properties, i.e., voltage levels, current levels, and temperatures.

Instructions embodying a method are recorded in the memory. Execution of the instructions by the processor causes the tool to receive the raw sensor data from the sensor suite, calculate SoC data for the battery elements, and automatically identify a threshold SoC imbalance in the ESS using the SoC data. Additionally, the tool identifies an element location within the ESS of a corresponding one of the battery elements having the threshold SoC imbalance. In one or more embodiments, the tool may also be caused to execute a control action in response to the threshold SoC imbalance to facilitate proactive operator responses, e.g., transmitting an electronic signal to an external device/graphical user interface (GUI) device that is indicative of the element location and SoC imbalance, trends in the SoC imbalance over time, and possibly visual alerts for battery elements nearing imbalance thresholds, and/or possibly performing other actions as set forth below. The tool is designed to interface with battery management systems (BMS), enabling adaptive balancing profiles that optimize charge distribution based on site-specific operational factors such as degradation models. The system architecture also supports compatibility with existing energy storage infrastructure, ensuring seamless deployment in both new and retrofit installations.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

FIG. 1 illustrates a simplified embodiment of an energy storage system (ESS) having a state of balance tool constructed in accordance with the disclosure.

FIG. 2A illustrates a portion of the ESS shown in FIG. 1.

FIGS. 2B and 2C illustrate non-limiting example constructions for implementing the ESS shown in FIGS. 1 and 2A.

FIG. 3 is a schematic illustration of an embodiment of the state of balance tool of FIG. 1.

FIG. 4 is a flow chart describing a method of determining a state of balance of the ESS of FIGS. 1 and 2A-2C using the tool illustrated in FIG. 3.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

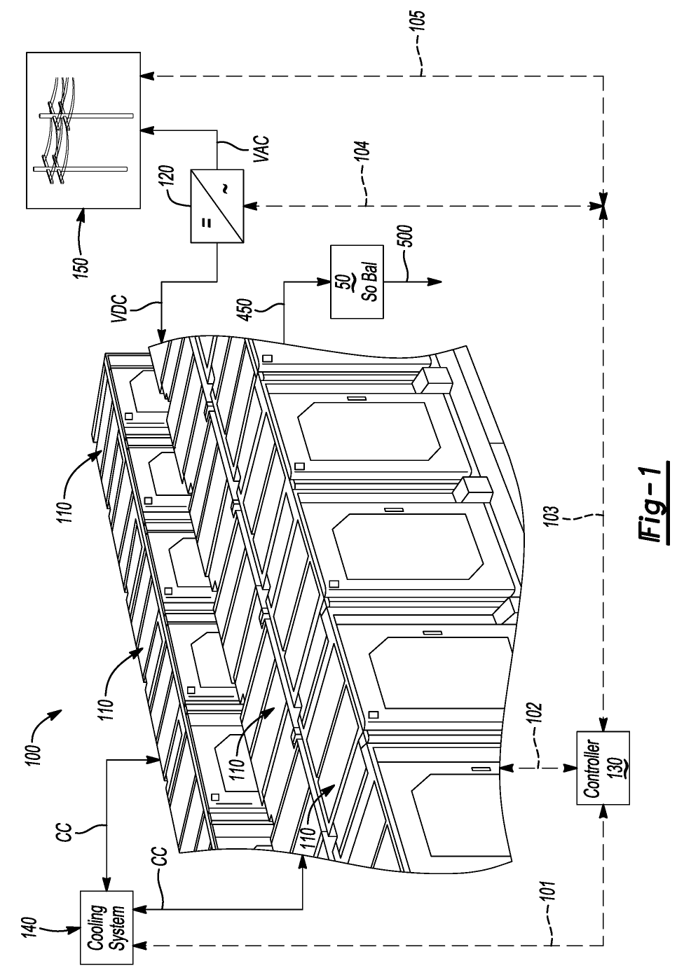

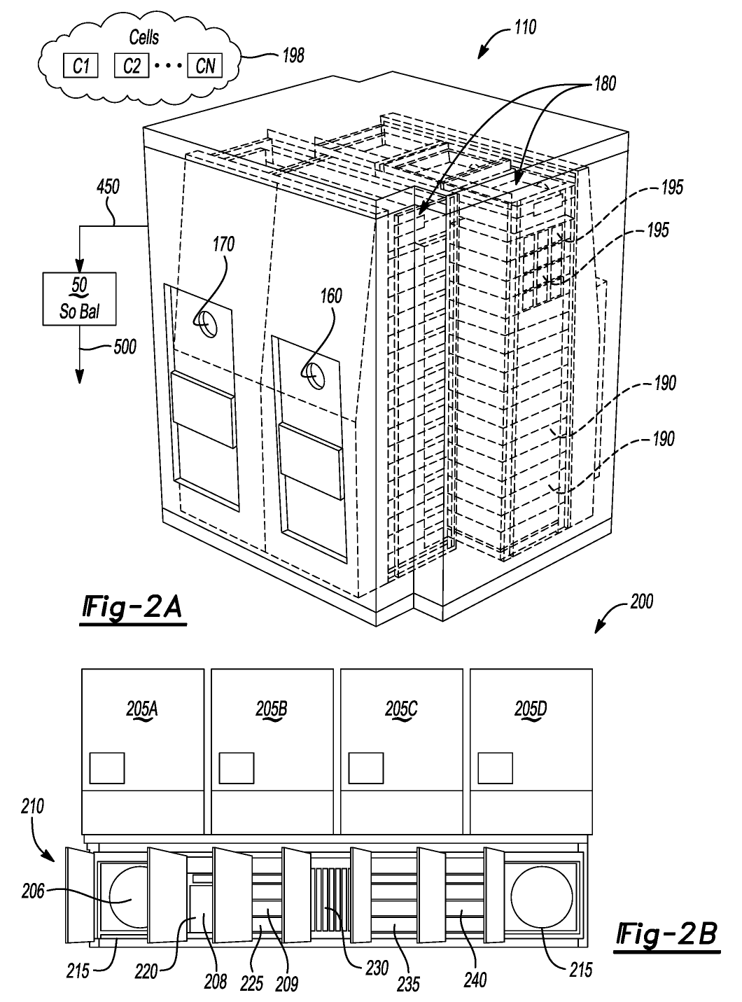

Referring to the drawings, wherein like reference numbers refer to the same or like components in the several Figures, FIG. 1 schematically illustrates a state of balance (So Bal) tool 50 for use with an energy storage system (ESS) 100, e.g., a battery power plant as shown. The ESS 100, an illustrated construction of which is simplified in FIGS. 1 and 2A for illustrative clarity, may include one or more energy storage units 110 each securing, containing, and supporting a collection of battery elements of the ESS 100. As shown in the representative energy storage unit 110 of FIG. 2A, for instance, such battery elements may include battery racks 190 each having one or more battery modules 195, which collectively form one or more corresponding electrochemical battery packs 180.

Each battery module 195 in the simplified illustration of FIG. 2A includes one or more series-connected (or possibly parallel-connected) electrochemical battery cells 198, e.g., a plurality of sealed lithium-ion cells or other high-energy energy storage cells. For clarity, the battery cells 198 are illustrated in FIG. 2A as nominal battery cells C1, C2, …, CN, with “N” being an application-specific integer value, e.g., hundreds or thousands of battery cells 198 depending on the total power capability of the ESS 100. The battery elements treated herein may include the battery cells 198 in one or more embodiments, with other embodiments possibly using the battery modules 195, battery packs 180, or battery racks 190 as the battery elements.

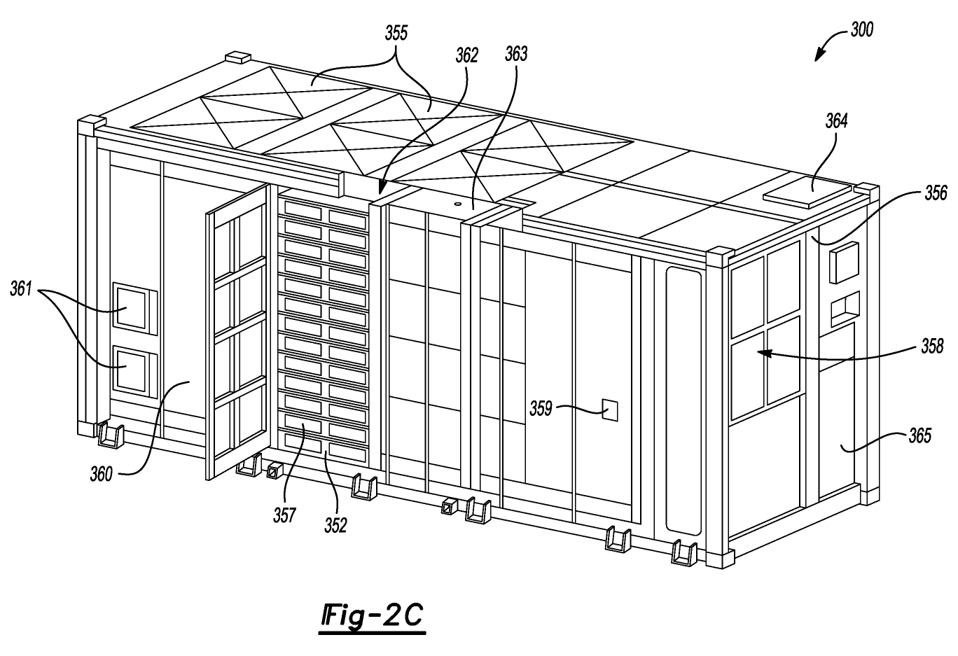

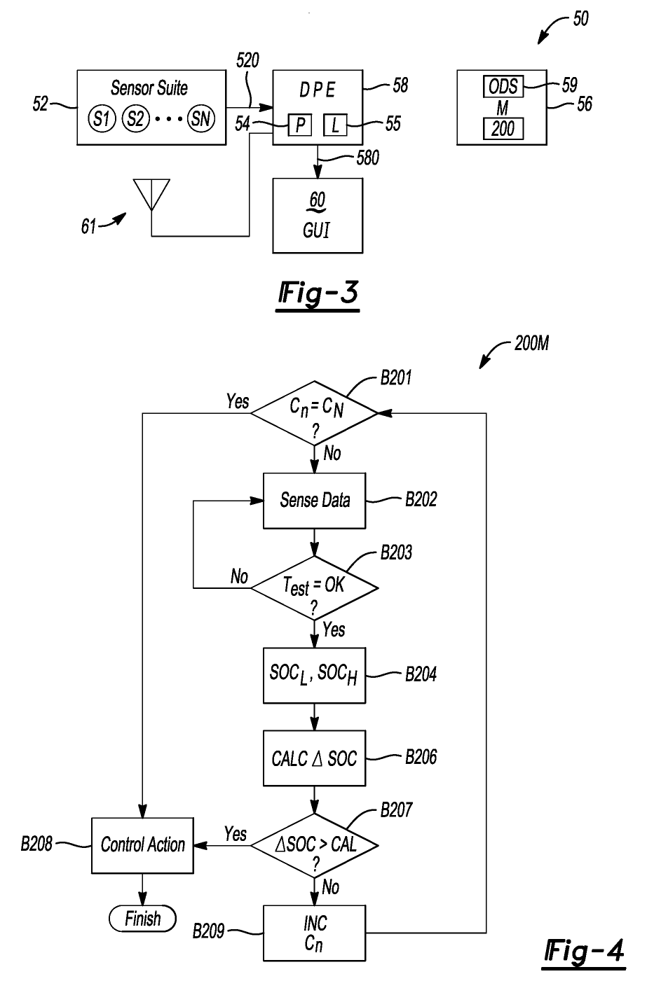

With respect to the So Bal tool 50 of FIG. 1, a representative construction of which is described in greater detail below with particular reference to FIGS. 3 and 4, this device is operable for locating and addressing state of charge (SoC) imbalances across constituent battery elements of the ESS 100, i.e., the various battery racks 190, modules 195, and/or battery cells 198 of FIG. 2A as noted above. The term “imbalance” as used herein refers to an electrical state in which a given battery element of the ESS 100 has a different SoC relative to other similarly constituted battery elements of the ESS 100. The tool 50 as described below provides a hardware and software-based approach for monitoring internal characteristics of the ESS 100 in real-time, proactively diagnosing potential imbalance states within the ESS 100, scheduling maintenance of adversely affected battery elements, and possibly correcting detected imbalances as needed. The tool 50 also may be integrated with existing battery management systems and operational reporting strategies, such that the tool 50 may be considered as an integral part of the ESS 100 or as a connectable maintenance device separate from the ESS 100 in different embodiments.

The representative ESS 100 illustrated in FIG. 1 may include a power conversion module ( = / ~ ) 120, a controller 130, and a cooling system 140, the latter of which may be external/separate from the ESS 100 or integral therewith in different implementations. The So Bal tool 50 is operable for receiving input signals 450 from the ESS 100, and possibly from the controller 130, the cooling system 140, and/or an external power source 150 such as an alternating current (AC) utility grid. The tool 50 is also operable for generating output signals 500 in response to performance of the method 200M of FIG. 4 as described below. While the tool 50 may be used with ESSs or battery power plants of alternative constructions, the ESS 100 of FIG. 1 is representative of a grid-scale, industrial strength energy storage infrastructure location/power plant or uninterruptible power supply (UPS), for example the commercially available Gridstack^{TM}.

The external power source 150 of FIG. 1 is connectable to the ESS 100 in one or more embodiments. The energy storage units 110 of the ESS 100 are electrically coupled to one another and operable for storing electrical power when such power is periodically provided by the external power source 150. For instance, the ESS 100 may receive AC power from the external power source 150 in the non-limiting example embodiment of FIG. 1 when consumer demand for such power is lower than the existing/non-supplemented capacity of the external power source 150. Conversely, the ESS 100 may offload stored electrical power to the external power source 150 via the power conversion module 120 when demand exceeds the capacity of the external power source 150.

In the non-limiting embodiment of FIG. 1, the power conversion module 120 remains central to management of power flow between the ESS 100 and the external power source 150. As shown, the power conversion module 120 outputs a DC voltage (VDC) to the ESS 100 or an AC voltage (VAC) to the external power source 150 as needed. Other embodiments may direct DC electrical power from the ESS 100, e.g., to a DC power station (not shown) in lieu of the AC-configured external power source 150, in which case the ESS 100 may include a DC-DC converter and suitable filtering components (not shown) for regulating the level of DC power flow between the ESS 100 and the external power source 150.

With respect to the cooling system 140 of FIG. 1, this component is coupled to the ESS 100 and the controller 130 to provide an application-suitable battery system coolant (CC) at a relatively low first temperature. As shown in FIG. 2A, such coolant may be circulated to the ESS 100 through one or more inlet ports 160. The ESS 100 may also discharge coolant back to the cooling system 140 of FIG. 1 at a relatively high second temperature from at least one outlet port 170. A representative embodiment of the cooling system 140 may include a heat exchanging system having a pump, a condenser, a heat exchange, and a sump, none of which are shown but all of which are well understood by those of ordinary skill in the art.

The controller 130 illustrated in FIG. 1 is embodied as one or more computer devices having requisite amounts and types of transitory and non-transitory memory, one or more processors, input/output circuity, etc., and is in wired or wireless networked communication with the So Bal tool 50, the energy storage units 110, the power conversion module 120, the cooling system 140, and the external power source 150. The controller 130 is configured to control ongoing operation of the ESS 100, the power conversion module 120, and the cooling system 140, and to manage communication of the same with the external power source 150. Thus, operation of the controller 130 unless otherwise specified is independent of operation of the tool 50 of the present disclosure.

For illustrative simplicity, control signals 104 and 105 are shown to represent communication between the controller 130 and the power conversion module 120 and external power source 150, respectively, with control signals 104 and 105 together forming (electronic or electrical) control signals 103 in FIG. 1. Similarly, communication between the controller 130 and the cooling system 140 may be achieved via electronic or electrical control signals 101, with similar control signals 102 used as a separate control channel for communicating with the various energy storage units 110. The term "signal" as used herein refers to any physically discernible indicator that conveys information, e.g., a suitable waveform (e.g., electrical, optical, magnetic, mechanical or electromagnetic), such as DC, AC, sinusoidal-wave, triangular-wave, square-wave, vibration, and the like, that is capable of traveling through a medium.

Referring briefly to FIG. 2B, the So Bal tool 50 of FIGS. 1 and 2A may be used with a modular node enclosure system 200 in one or more embodiments. The example modular node enclosure system 200 may include a “smart skid” 210 having a plurality of pods, e.g., 205A, 205B, 205C, and 205D and plurality of bays 215, 220, 225, 230, 235, and 240 each configured to secure one or more components associated with the ESS 100 of FIG. 1. In some configurations, the bays 215-240 of the example smart skid 210 may include one or more of a chiller bay 215, a power conversion system (PCS) bay 220, a direct current protection module (DCPM) bay 225, an auxiliary bay 230, a fire control bay 235, and a plumbing bay 240. In other implementations, the smart skid 210 may include a different quantity of bays and/or differently constructed or equipped bays. Similarly, one or more bays of the smart skid 210 may be combined, modified, omitted, and/or replaced in one or more implementations.

The chiller bay 215 in a non-limiting embodiment of the modular node enclosure system 200 may be configured to hold/secure one or more chillers 206 to aid battery cooling. The PCS bay 220 may be configured to hold/secure at least one PCS 208, which may provide a required power flow to the external power source 150 of FIG. 1 by discharging one or more energy storage units 110. Similarly, the PCS 208 may provide a required power flow from an energy system (e.g., the external power source 150) for charging one or more energy storage units 110 or other nodes. In some constructions, the PCS bay 220 may be further configured to hold/secure one or more inverters and/or one or more battery management systems. Further, the PCS 208 may be coupled to at least one transformer (not shown) configured to step up or step down the required power flow to and from the external power source 150, such as AC or DC voltage.

The PCS 208 of FIG. 2B may be configured to standardize power inputs and outputs to and from one or more energy storage nodes. The PCS 208 may generally include and/or connect to one or more of the following: an inverter for converting the DC source of the energy storage nodes to an AC waveform, and vice versa; a DC/DC converter for converting the DC source of the energy storage nodes to a different DC source characteristic; an AC/AC converter for converting one form of AC energy (e.g., voltage, frequency, etc.,) to another form of AC energy; an AC/DC converter for converting AC energy to DC energy (or vice versa); a transformer; other known or later developed power conversion elements; and/or other components depending on the application.

The DCPM bay 225 of FIG. 2B may be configured to hold/secure at least one DCPM 209, as well as one or more HVAC components (not shown) to manage and maintain thermal conditions (e.g., temperature, humidity, etc.,) of the modular node enclosure system 200. In some aspects, the DCPM bay 225 may be configured to hold/secure at least one battery management system (BMS). For example, at least one BMS may be disposed with/near at least one DCPM 209. In other aspects, at least one BMS may be housed/secured in at least one additional/alternative bay of the smart skid 210.

Still referring to FIG. 2B, the auxiliary bay 230 may be configured to hold/secure one or more auxiliary components such as spare parts, controls, electronic equipment, and/or miscellaneous items. Without limitation, such auxiliary components may include any one or more of a controller assembly, an uninterruptible power supply (UPS), a programmable logic controller (PLC), an electrical box, analog/digital converters, circuit breakers, fuses, power cabling, etc. In some aspects, the auxiliary bay 230 may be configured to hold/secure at least one BMS. For example, the node enclosure system 200 may comprise at least one system BMS housed within the auxiliary bay 230. In such aspects, the system BMS may comprise a software-defined system BMS that runs on at least one component within the auxiliary bay 230 such as a controller e.g., control assembly, enclosure controller, etc.

The fire control bay 235 of FIG. 2B may be configured to hold/secure a fire control panel. The fire control bay 235 may also be configured to hold/secure one or more high-voltage components such as any one or more of a power distributor, switchgear, breaker, converter, or the like. The plumbing bay 240 for its part may be configured to hold plumbing equipment, which may be connected to one or more of the chillers 206. The chiller bay 215 and/or the plumbing bay 240 may be configured to hold/secure one or more cooling conduits configured to carry coolant, which may be used to maintain heating and cooling within/throughout various parts of the enclosure system 200.

Referring now to FIG. 2C, another modular node enclosure system 300 is illustrated according to an additional embodiment of the disclosure, with any/all of the above described components being containable on or within the node enclosure system 300. The modular node enclosure system 300 may include an application suitable number of corresponding ESSs 100 (FIG. 1) and/or be implemented in any suitable type of ESS. The node enclosure system 300 may securely contain therein one or more of the controller 130 (FIG. 1), a direct current protection module(s) (DCPM) 352, HVAC systems and a DC disconnect switch (not shown), deflagration panels 355, an uninterrupted power supply (UPS) 356, battery modules 357, a chiller compartment 358, a fast stop (F-stop) 359, one or more enclosure doors 360, an inlet louver or louvers 361, multi detectors 362, and a hydrogen (H2) gas detector 363. Other components may include a vent panel 364, an enclosure side door 365, and a battery cooling plate door (not shown).

In some implementations, one or more of the noted components may be combined, omitted, modified, and/or replaced. Similarly, other implementations of the node enclosure system 300 (or 200 of FIG. 2B) may include one or more additional/alternative components. The construction of FIGS. 1 and 2A-2C are therefore non-limiting example systems that may be used with the So Bal tool 50 of the present disclosure without limitation, with the tool 50 now described with reference to the remaining Figures.

Referring to FIG. 3, the So Bal tool 50 for use with the ESS 100 of FIG. 1 and its constituent energy storage units 110 (e.g., FIG. 1) is shown schematically for illustrative simplicity and clarity. The tool 50 may operate as a portable control unit, e.g., a laptop or tablet computer, having components and circuitry in the form of various combinations of Application Specific Integrated Circuit(s) (ASIC), Field-Programmable Gate Array (FPGA), electronic circuit(s), central processing unit(s), for example one or more microprocessor(s) and associated memory component(s).

In one or more embodiments, the So Bal tool 50 may include a sensor suite 52, one or more processors (P) 54, and non-transitory computer storage medium (“memory”) (M) 56. The sensor suite 52 is operable for sensing raw sensor data 520 of designated battery elements within the ESS 100 of FIG. 1, including voltage levels, current levels, and temperatures, and reporting the same to the processor 54. Temperature data in particular may not be sensed at each of the battery elements, but rather at various locations within the ESS 100. In one or more implementations, the tool 50 may operate in a cloud-based processing environment, i.e., the tool 50 may be placed in remote communication with a server, cloud network, or other backend architecture over an internet connection or other wireless/remote communication channel. In such an application, the raw sensor data 520 is received and processed using a virtual server environment, as will be appreciated by one of ordinary skill in the art. The raw sensor data 520 is ultimately used by the tool 50 to determine corresponding SoCs of each respective one of the battery elements, e.g., the battery rack 190, modules 195, and/or battery cells 198 (FIG. 2A), or larger or smaller strings/groups of such battery cells 198 in different implementations.

The memory 56 of FIG. 3 may include transitory and non-transitory memory component(s) and storage devices, e.g., read-only memory (ROM), electronic programmable read only memory (EPROM), random access memory (RAM), optical or magnetic hard drive, etc. Non-transitory memory components of the memory 56 are capable of storing machine readable instructions in the form of one or more software or firmware programs or routines, combinational logic circuit(s), input/output circuit(s) and devices, signal conditioning and buffer circuitry and other components that may be accessed by one or more processors to provide a described functionality. Input/output circuit(s) and devices include analog/digital inverters and related devices that monitor inputs from sensors, with such inputs monitored at a preset sampling frequency or in response to a triggering event. Software, firmware, programs, instructions, control routines, code, algorithms, and similar terms mean controller-executable instruction sets including calibrations and temperature-specific and hysteresis-adjusted look-up tables.

Various approaches can be used within the scope of the disclosure to determine cell-level (or larger) SoCs in real time. This may occur using the SoBal tool 50 of FIG. 3 during ongoing operation of the ESS 100. For example, the sensor suite 52 may include a plurality of embedded voltage sensors S1 each operable for measuring a voltage level at a given battery element of the ESS 100, for instance a cell voltage. While embodiments may be used in which the voltage sensor S1 is used to sense a voltage level of a given one of the battery cells 198 of FIG. 2A, such that a cell sense board (not shown) measures and outputs a corresponding cell voltage for each respective one of the battery cells 198, the present teachings may be applied to strings or larger groups of battery cells. For instance, sensing may occur at the level of the battery racks 190 and/or battery modules 195 of FIG. 2A for rack or module-level imbalance detection, without limitation.

The memory 56 illustrated in FIG. 3 may be programmed herein to associate the sensed cell/module/submodule voltages with a temperature-specific and hysteresis-adjusted voltage-to-SoC lookup tables determined offline and stored in non-transitory portions of the memory 56. This enables precise SoC estimation across varying operating conditions. Hysteresis as considered herein refers to an electrochemical effect where the open circuit voltage (OCV) for a specific SoC will be higher after charging and lower after discharging. This voltage difference does not disappear when the battery is at rest. A correction is therefore made to compensate for this effect when calculating an accurate SoC.

Other approaches may be used for determining the SoC, including but not limited to performing real-time Coulomb counting via the processor 54 during operation of the ESS 100 receiving and using current values from one or more current sensors S2, and then integrating the measured currents over time to determine a total charge. The processor 54 may then compare the calculated total charge to a predetermined maximum capacity of the battery cell to determine the SoC, with SoC ranging from 0% (fully depleted) to 100% (fully charged). Such techniques could be augmented by predictive algorithms or machine learning logic to accurately determine respective SoC levels at various locations within the ESS 100 of FIG. 1 at a desired level of granularity, i.e., at a level of the battery racks 190, the battery modules 195, or the individual battery cells 198 of FIG. 2A.

In general, the memory 56 of FIG. 3 is used to store computer-readable code or instructions. The execution of the code by the processor 54 causes the So Bal tool 50 to receive the raw sensor data 520 from the sensor suite 52 and thereafter process the raw sensor data 520 using a secure cloud service as noted above, e.g., AMAZON Web Services (AWS^{®}), to identify imbalances in the respective SoCs. Within the memory 56 may exist an Operational Data Store (ODS) 59, i.e., a database or other permanent/non-volatile data archive which holds a historical record of operating data of the ESS 100, including the measured voltages, currents, temperatures, Coulomb count values, dates and times of measurement, ambient conditions, external load/demand conditions, etc., which are ultimately used to determine or inform the relevant SoCs.

The example SoBal tool 50 of FIG. 3 may also include a real-time Data Processing Engine (DPE) 58, with the DPE 58 including the processors (P) 54 and associated logic circuits (L) 55 for performing the method 200M of FIG. 4. A graphical user interface (GUI) device 60 may be included as part of the tool 50 to receive GUI control signals 580 transmitted by or otherwise provided from the DPE 58 as electronic control signals, with a graphic display setting of the GUI device 60 being controlled in response to the GUI control signals 580. The GUI device 60 as envisioned herein may be a user-friendly display screen or other intuitive interface operable for displaying the present status of the ESS 100, quantifying state of balance issues, locating affected battery elements, and displaying at least the state of balance and a location of any imbalance in the ESS 100, and/or trends in changes in the SoC imbalance over time. In this manner the GUI device 60 provides intuitive guidance to maintenance personnel or operators of the ESS 100 regarding appropriate steps to take to address detected SoC imbalances.

To facilitate communication with external devices such as the ESS 100 and the controller 130 of FIG. 1, the SoBal tool 50 of FIG. 3 may also include one or more radio frequency (RF) transceivers 61. The RF transceiver(s) 61 are operable for establishing a communications link between the tool 50 and the controller 130 of FIG. 1, maintaining communication with the controller 130, receiving some or all of the input signals 450, and transmitting the output signals 500 of FIGS. 1 and 2A in a wireless manner. In this manner, the tool 50 may remain in secure remote communication with the controller 130 and other components of the ESS 100 in one or more embodiments.

Referring now to FIG. 4, the method 200M noted above is described in terms of discrete code segments or logic blocks. Each logic block is executable by the DPE 58 and its resident processor(s) 54 (FIG. 3) to perform the described calculations in the overall control of the ESS 100 of FIG. 1.

Beginning with block B201 (“Cn = C_{N}?”), the method 200M may include determining if a current battery element, e.g., a nominal battery cell Cn, is the N^{th} battery element to be evaluated in a given analysis. That is, if the ESS 100 of FIG. 1 includes 1,000 battery cells 198 (FIG. 2A), such that N = 1000, then the processor 54 of the DPE 58 of FIG. 3 in one or more embodiments would assign a unique numeric identifier (n) to each battery element, where n = 1 to 1000 in this non-limiting example. The method 200M may proceed to block B208 when the current battery element is the N^{th} battery element, i.e., Cn = C_{N}, thus signaling that all battery elements have been analyzed. The method 200M otherwise proceeds to block B202.

At block B202 (“Sense Data”), the method 200M includes using the sensor suite 52 of FIG. 3 to sense the raw sensor data 520 as part of the input signals 450. The particular composition of the raw sensor data 520 may vary with the manner in which the processor 54 will calculate or otherwise determine the SoC, with the raw sensor data 520 possibly including cell voltages, currents, temperature, Coulomb count, etc. The method 200M proceeds to block B203 once the raw sensor data 520 has been sensed for battery element (n).

At block B203 (“Tₑₛₜ = OK?”), the method 200M includes identifying a threshold relaxation time period (Tₑₛₜ) in which an accurate estimate of the SoC can be generated. The value of the relaxation time period may be predetermined or calibrated, and may range from several minutes to about an hour depending on operating conditions of the ESS 100. Block B202 is repeated in a loop with block B203 until the threshold relaxation time period is reached, at which point the method 200M proceeds to block B204.

Block B204 (“SOC_{L}, SOC_{H}”) entails determining, for the set of battery elements already evaluated under method 200M, a lowest and highest SoC, i.e., SoC_{L} and SoC_{H}, respectively. These SoC values for these two elements, e.g., a pair of the battery cells 198 having the lowest and highest SoC in the ESS 100 of FIG. 1, are saved in memory 56 of FIG. 3. The method 200M thereafter proceeds to block B206.

B206 (“CALC ΔSOC”) includes calculating the difference between the lowest and highest SoCs from block B204, i.e., ΔSOC = SoC_{H} - SoC_{H}. This value is saved in memory 56 as part of the data stored in the ODS 59 of FIG. 3. The method 200M thereafter proceeds to block B207.

At block B207 (“ΔSOC > CAL?”) the method 200M includes comparing the difference between the lowest and highest SoCs, i.e., ΔSOC, to a user-defined SoC imbalance threshold, e.g., one that is adaptable to different system requirements. The method 200M proceeds to block B208 when the difference between the lowest and highest SoCs exceeds the SoC imbalance threshold, and to block B209 in the alternative.

B208 (“Control Action”) includes executing one or more control actions via the SoBal tool 50 of FIGS. 1-3 in response to the state of charge difference, i.e., ΔSOC from block B206. Possible control actions within the scope of the disclosure may include identifying an element location of the particular battery element having the lowest SoC in block B204, for example a unique alphanumeric cell identifier for a given battery cell 198 having the lowest SoC. Block B208 thereafter includes transmitting a suitable alert signal or displaying a graphic overlay/annotation to maintenance personnel or a user of the ESS 100 of FIG. 1 indicating the precise location in the ESS 100, and possibly historical trends in changes in the SoC imbalance over time. Additionally, automated or operator-controlled actions in response to the SoC imbalance may be initiated such as balancing, isolating the battery element having the SoC imbalance, or notifying an operator.

For example, in response to the conditions at block B207, i.e., ΔSOC exceeding a calibrated or predetermined threshold, the processor 54 of FIG. 3 may communicate the location of the battery element having the lowest SoC to the GUI device 60 as part of the GUI control signals 580. As each battery element is evaluated in turn by the SoBal tool 50 of FIGS. 1-3 when performing the method 200, the tool 50 will have identified the lowest SoC for the ESS 100 as a whole upon evaluating each of the battery elements. The GUI device 60 can thereafter display an image and/or a three-dimensional model of the ESS 100 of FIG. 1, which in turn may be annotated with the element location of the lowest SoC battery element, e.g., as an overlay, alphanumeric text, etc. Such information may be helpful in directing maintenance personnel/user to the precise location of the low SoC battery element.

In other implementations, the processor 54 of the DPE 58 shown in FIG. 3 may automatically schedule maintenance actions based on the results of the method 200M. This action may occur in a forward-looking or preemptive manner. For example, as the SoBal tool 50 may be used in conjunction with the controller 130 of FIG. 1 or integrated into functions thereof, the processor 54 can observe and track trends in the ΔSOC value calculated as part of the method 200. Given the current ΔSOC and a calculated rate of increase thereof, the tool 50 of FIG. 3 would be able to schedule maintenance actions in advance of the ΔSOC reaching a critically elevated level, thereby enhancing operational efficiency and reliability of the ESS 100 shown in FIG. 1.

In addition to such control actions, the information recorded in the ODS 59 as part of the method 200M may be used to generate comprehensive histories of the performance of ESS 100. The ability of the SoBal tool 50 of FIG. 3 to integrate with existing systems in turn enhances data fluidity and reporting efficiency. Other control actions not described herein may be performed as part of block B208, including requesting control intervention by the controller 130, via the processor 54, to isolate any low SoC battery elements to the extent possible, for instance by switching control actions that would remove the low SoC battery element from the circuit. As appreciated, such a capability requires inclusion of switching circuits into the ESS 100 that, when activated, would bypass the low SoC battery element to extend operation of the ESS 100 until maintenance can be properly performed. The method 200M is finished upon completion of one or more control actions at block B208.

Block B209 (“INC Cn”) of the method 200M includes incrementing a counter value (Cₙ), i.e., Cₙ = Cₙ₊₁, before proceeding to block B201. As described above with reference to block B201, the method 200M continues for each of N battery elements of the ESS 100, starting with a nominal element n = 1 and continuing until element n = N has been evaluated. Thus, performance of block B209 upon evaluating a nominal element n = 1 at the first iteration of method 200M would result in the counter value increasing to n = 2, and then n = 3, etc., at subsequent iterations of the method 200.

By using the SoBal tool 50 of FIGS. 1-3 to implement the method 200M as described above, an automated approach is enabled for monitoring and addressing imbalances in the ESS 100 illustrated in FIG. 1. Insights gained using the method 200M may help maintenance personnel prioritize maintenance efforts, improve energy availability to the external power source 150 of FIG. 1 when demand for such energy is high, and reduces operational costs by directing field service engineers to specific problem areas.

Along with such benefits, the method 200M also enables an intuitive approach to avoiding a “stranded energy” state in which energy capacity of the ESS 100 of FIG. 1 is inaccessible due to the threshold low SoC of a battery element thereof. As will be appreciated by skilled artisans in view of the foregoing disclosure, the method 200M may enable analysis of historical SoC imbalance trends to predict future imbalances and schedule preventive maintenance actions. Control actions may be executed in response to the method 200M, e.g., by transmitting an electronic signal indicative of the element location to initiate SoC balancing efforts, isolate the element having the SoC imbalance, and/or notifying an operator of the SoC imbalance. These and other benefits will be readily appreciated by those skilled in the art now having the benefit of the foregoing disclosure.

The present disclosure may be embodied in many different forms. Representative examples are shown in the various drawings and described herein in detail as non-limiting examples of the disclosed principles. To that end, elements and limitations described herein, but not explicitly set forth in the claims, are not to be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof.

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the appended claims.

We claim:

1. A state of balance tool for an energy storage system (ESS) having a plurality of electrochemical battery elements, comprising:
a processor; and
a computer storage medium (“memory”) on which is recorded instructions, wherein execution of the instructions by the processor causes the tool to:
receive raw sensor data from a sensor suite of the ESS;
determine state of charge (SoC) data for the battery elements using the raw sensor data to identify a threshold SoC imbalance in the ESS;
identify an element location in the ESS of a corresponding one of the battery elements having the threshold SoC imbalance; and
execute a control action in response to the threshold SoC imbalance, including transmitting an electronic signal to an external device that is indicative of the threshold SoC imbalance and the element location.

2. The tool of claim 1, further comprising:
the sensor suite, wherein the sensor suite includes a plurality of voltage sensors operable for sensing voltage levels of each respective one of the battery elements, the SoC data includes the voltage levels, and wherein the execution of the instructions by the processor causes the tool to determine a corresponding SoC of each of the battery elements using the voltage levels.

3. The tool of claim 2, wherein the execution of the instructions by the processor causes the tool to reference one or more temperature-specific and hysteresis-adjusted voltage-to-SoC lookup tables to ensure precise SoC estimation across varying operating conditions.

4. The tool of claim 2, wherein the sensor suite includes a plurality of current sensors operable for sensing current levels of each respective one of the battery elements, the raw sensor data includes the current levels, and wherein the execution of the instructions by the processor causes the tool to determine a corresponding SoC of each of the battery elements using the current levels.

5. The tool of claim 4, wherein the execution of the instructions by the processor causes the tool to determine the corresponding SoC of each of the battery elements using the current levels and Coulomb counting.

6. The tool of claim 1, wherein the execution of the instructions by the processor causes the tool to identify the threshold SoC imbalance in the ESS using the SoC data by calculating a difference between a lowest SoC and a highest SoC of the battery elements, and comparing the difference to a user-configurable threshold indicative of the threshold SoC imbalance.

7. The tool of claim 1, wherein the battery elements include a plurality of electrochemical battery cells of the ESS.

8. The tool of claim 1, further comprising:
a graphical user interface (GUI) device, wherein the execution of the instructions by the processor causes the tool to transmit a GUI control signal to the GUI device as part of the electronic signal to thereby cause the GUI device to display the element location and/or trends in changes in the SoC imbalance over time.

9. The tool of claim 8, wherein the execution of the instructions by the processor causes the tool to transmit the GUI control signal to the GUI device as part of the electronic signal to thereby cause the GUI device to display the element location and/or trends in changes in the SoC imbalance over time as an overlay or annotation on an image or model of the ESS.

10. The tool of claim 1, further comprising a radio frequency (RF) transceiver, wherein the tool is in remote communication with a controller of the ESS via the RF transceiver.

11. A method for use with an energy storage system (ESS) having a plurality of electrochemical battery elements, comprising:
receiving raw sensor data from a sensor suite via a state of balance tool;
identifying a threshold state of charge (SoC) imbalance in the ESS via a processor of the tool using the raw sensor data;
identifying an element location in the ESS of a corresponding one of the battery elements having the threshold SoC imbalance; and
executing a control action via the processor in response to the threshold SoC imbalance, including transmitting an electronic signal indicative of the threshold SoC imbalance and the element location.

12. The method of claim 11, wherein the battery elements include a plurality of electrochemical battery cells, and wherein transmitting the electronic signal indicative of the element location includes transmitting the element location as a unique alphanumeric cell identifier.

13. The method of claim 11, wherein receiving the raw sensor data from the sensor suite includes receiving voltage levels of each respective one of the battery elements and the raw sensor data includes the voltage levels, the method further comprising:
determining a corresponding SoC of each of the battery elements via the processor using the voltage levels and one or more temperature-specific and hysteresis-adjusted voltage-to-SoC lookup tables to ensure precise SoC estimation across varying operating conditions.

14. The method of claim 11, wherein receiving the raw sensor data from the sensor suite includes receiving current levels of each respective one of the battery elements and the raw sensor data includes the current levels, the method further comprising:
determining a corresponding SoC of each of the battery elements using the current levels.

15. The method of claim 14, wherein determining a corresponding SoC of each of the battery elements using the current levels includes performing a Coulomb counting process using the current levels.

16. The method of claim 11, wherein identifying the threshold SoC imbalance in the ESS using the raw sensor data includes:
calculating a difference between a lowest SoC and a highest SoC of the battery elements; and
comparing the difference between the lowest SoC and the highest SoC of the battery elements to a calibrated threshold indicative of the threshold SoC imbalance.

17. The method of claim 11, further comprising:
displaying the element location and/or trends in changes in the SoC imbalance over time via a GUI device.

18. The method of claim 17, wherein displaying the element location via the GUI device includes displaying an overlay or annotation on an image or model of the ESS.

19. The method of claim 11, further comprising:
establishing a communications link between the tool and a controller of the ESS via a radio frequency (RF) transceiver; and
communicating remotely with the controller of the ESS via the RF transceiver.

20. A battery power plant, comprising:
an energy storage system (ESS) having:
a plurality of energy storage units;
a plurality of electrochemical battery cells positioned in the plurality of energy storage units;
a controller operable for controlling operation of the ESS; and
a computerized state of balance tool in communication with the ESS, the tool including:
a sensor suite, including a plurality of voltage sensors, current sensors, and temperature sensors;
a graphical user interface (GUI) device;
a processor; and
a computer storage medium (“memory”) on which is recorded instructions, wherein execution of the instructions by the processor causes the tool to:
receive raw sensor data from the sensor suite;
identify a threshold state of charge (SoC) imbalance in the ESS using the raw sensor data by calculating a difference between a lowest SoC and a highest SoC of the battery cells, and comparing the difference between the lowest SoC and the highest SoC of the battery cells to a calibrated threshold indicative of the threshold SoC imbalance;
identify a location in the ESS of a corresponding one of the battery cells having the threshold SoC imbalance; and
execute a control action in response to the threshold SoC imbalance, including transmitting a GUI control signal to the GUI device to thereby cause the GUI device to identify the threshold SoC imbalance and display the location in the ESS of the corresponding one of the battery cells having the threshold SoC imbalance.
